(19) United States
(12) Patent Application Publication
(10) Pub. No.: US 2024/0178237 A1
(43) Pub. Date: May 30, 2024

(54) DISPLAY DEVICE AND TILING DISPLAY APPARATUS INCLUDING THE DISPLAY DEVICE

(71) Applicant: LG Display Co., Ltd., Seoul (KR)

(72) Inventors: Won-Gyu JEONG, Paju-si (KR); Joong-Ha LEE, Paju-si (KR); Da-Young KIM, Paju-si (KR)

(21) Appl. No.: 18/517,477

(22) Filed: Nov. 22, 2023

(30) Foreign Application Priority Data
Nov. 30, 2022 (KR) 10-2022-0164457

(51) Int. Cl. H01L 27/12; H01L 25/16

(52) U.S. Cl. CPC H01L 27/124; H01L 25/167

(57) ABSTRACT

A display device includes a first substrate including light-emitting elements disposed on one surface thereof; a second substrate bonded to an opposite surface to the one surface of the first substrate; a plurality of side wirings electrically connecting the first substrate and the second substrate to each other; a wiring protection member covering the side wirings; wherein the wiring protection member includes a protective layer and a plurality of conductive particles dispersed in the protective layer.

### CROSS-REFERENCE TO RELATED APPLICATION

This application claims priority from Korean Patent Application No. 10-2022-0164457 filed on Nov. 30, 2022, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more particularly, to a display device including a side surface protection structure for protecting a side wiring of the display device, and a tiling display apparatus including the display device.

### Description of Related Art

A display device is applied to various electronic devices such as TVs, mobile phones, laptops, wearable device, vehicle, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source (e.g., LCD), and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source.

### BRIEF SUMMARY

The organic light-emitting display device (OLED), due to material characteristics of the organic material within the light-emitting layer of the OLED device, is vulnerable to moisture and oxygen. Accordingly, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

Further benefits of the micro-LED display device include that it is resistant to the external environment, and thus does not require a protective structure such as a sealing material, and various types of materials may be used as a material of a substrate of the device. Thus, the micro-LED display device may be thinner than the organic light-emitting display device and is more advantageous in being implemented as a flexible display device. The plurality of micro-LED display devices may be arranged in a matrix manner to implement a tiling display apparatus.

When arranging the plurality of micro-LED display devices in the matrix manner to implement the tiling display apparatus, a structure, for example, a bezel for visually blocking a non-display area surrounding a display area from the user's field of view is disposed. As the bezel width increases, the bezel may be visible to the user such that the user's image immersion decreases. Thus, research is being conducted to form a minimum bezel area.

The various embodiments of the present disclosure provide a display device including a side wiring structure capable of suppressing migration between materials of a plurality of side wiring configured to electrically connect an upper substrate and a lower substrate to each other in the display device.

Further, various embodiments of the present disclosure delay a time at which the migration occurs, thereby improving reliability of a display device.

Further, various embodiments of the present disclosure provide a display device capable of realizing a substantially zero bezel area in which a bezel area is disposed in a minimum space or is substantially absent.

The technical benefits according to the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the benefits and advantages according to the present disclosure may be realized using means shown in the claims or combinations thereof.

A display device according to a first embodiment of the present disclosure includes a first substrate having a plurality of light-emitting elements disposed on one surface thereof; a second substrate bonded to an opposite surface to the one surface of the first substrate; a plurality of side wiring electrically connecting the first substrate and the second substrate to each other; a wiring protection member covering the side wiring; and a side sealing member covering the side surface portion, wherein the wiring protection member includes a protective layer and a plurality of conductive particles dispersed in the protective layer.

A tiling display apparatus according to a second embodiment of the present disclosure includes a plurality of display devices arranged in a tiling manner, wherein each of the plurality of display devices includes the display device according to the first embodiment of the present disclosure, wherein the plurality of display devices are arranged such that the side sealing members of adjacent ones of the plurality of display devices are adjacent to each other.

According to the embodiments of the present disclosure, the wiring protection member that protects the side wiring used to electrically connect the upper substrate and the lower substrate to each other in the display device includes the protective layer and the conductive particles dispersed in the protective layer, thereby suppressing a migration phenomenon in which metal ions of one side wiring move to another side wiring adjacent thereto.

Accordingly, there is an effect of delaying the occurrence time of the migration phenomenon in which the metal ions of the side wiring move to the adjacent side wiring. This may suppress occurrence of a short-circuit defect between adjacent side wirings due to the migration phenomenon.

Further, delaying the migration occurrence time may result in preventing a defect in which an image is not displayed on a display area of the display device, such that product reliability may be improved.

Further, delaying the time at which the migration phenomenon occurs may result in improving the lifespan of the product and suppressing the increase in the power consumption to implement a low-power product.

Further, controlling a width of the side sealing member via the laser cutting may allow the bezel area to be disposed in a minimum space or to implement a zero bezel area in which a bezel area is substantially absent.

Effects of the present disclosure are not limited to the effects mentioned above, and other effects not mentioned will be clearly understood by those skilled in the art from the descriptions below.

### BRIEF DESCRIPTION OF THE SEVERAL VIEWS OF THE DRAWINGS

FIG. 1 is a schematic plan view of a tiling display apparatus according to an embodiment of the present disclosure.

FIG. 2 is a schematic perspective view of one display device constituting the tiling display apparatus of FIG. 1.

FIG. 3 is a cross-sectional view of taken along the line 3-3 in FIG. 1.

FIG. 4 is an enlarged view of reference 4 in FIG. 3.

FIG. 5 to FIG. 12 are diagrams shown to illustrate a manufacturing method of a display device according to an embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure.

For simplicity and clarity of illustration, elements in the drawings are not necessarily drawn to scale. A shape, a size, a dimension (e.g., length, width, height, thickness, radius, diameter, area, etc.), a ratio, an angle, a number, etc., disclosed in the drawings for describing embodiments of the present disclosure are illustrative, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer or may be disposed indirectly on the second element or layer with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after.” “subsequent to.” “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first.” “second.” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range or tolerance unless there is separate explicit description thereof.

It will be understood that when an element or layer is referred to as being “connected to,” or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A term “device” used herein may refer to a display device including a display panel and a driver for driving the display panel. Examples of the display device may include a light emitting diode (LED), and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including LED and the like, but embodiments of the present disclosure are not limited thereto.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each embodiment of the present disclosure will be described with reference to the accompanying drawings.

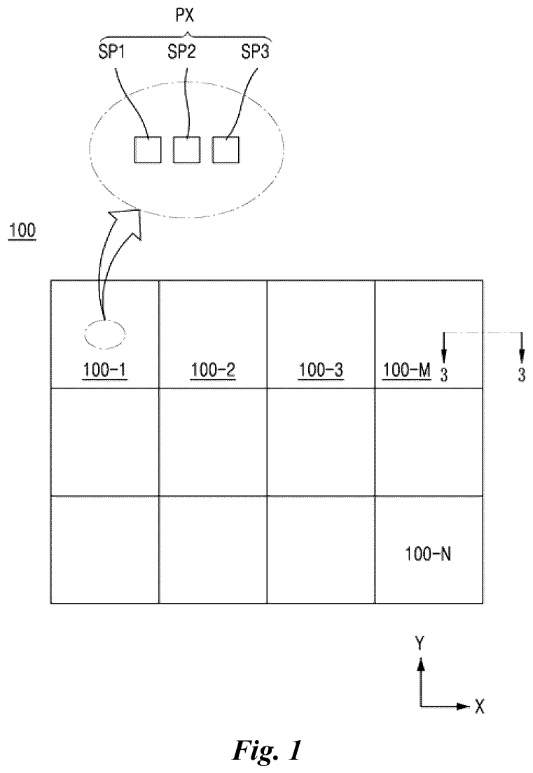

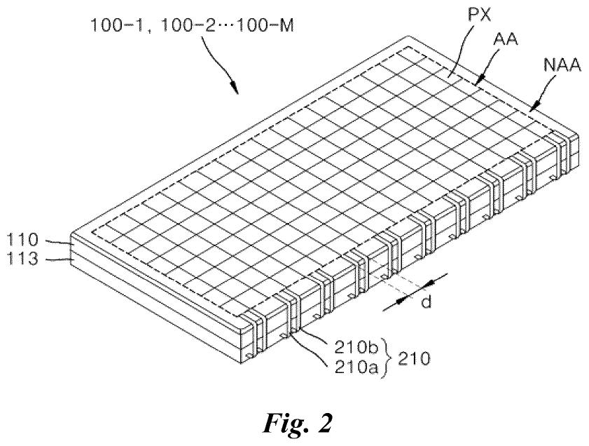

FIG. 1 is a schematic plan view of a tiling display apparatus according to an embodiment of the present disclosure. FIG. 2 is a schematic perspective view of one display device constituting the tiling display apparatus of FIG. 1. All the components of cach tiling display apparatus according to all embodiments of the present disclosure are operatively coupled and configured.

Referring to FIG. 1 and FIG. 2, a tiling display apparatus 100 according to an embodiment of the present disclosure may be configured to include a plurality of display devices 100-1, 100-2, 100-3 . . . 100-M and 100-N. In this regard, M and N may be natural numbers. The display device 100-1, 100-2, 100-3 . . . 100-M and 100-N may be arranged in a tiling manner such that adjacent display devices contact each other while the display devices are arranged along a first direction X and a second direction Y crossing the first direction X. The first direction X may be a longitudinal direction, and the second direction Y may be a transverse direction. , but embodiments of the present disclosure are not limited thereto. For example, the first direction X may be a transverse direction, and the second direction Y may be a longitudinal direction. Alternatively, the first direction X may be any direction, and the second direction Y may be a direction that intersects perpendicular to the first direction X.

Each of a plurality of pixels PX disposed in each of the plurality of display devices 100-1, 100-2, 100-3 . . . 100-M and 100-N may include a plurality of sub-pixels SP1. SP2, and SP3. Each of the plurality of sub-pixels SP1, SP2, and SP3 may include a first light-emitting element, a second light-emitting element, or a third light-emitting element that emits red (R), green (G), or blue (B) light, respectively. However, the present disclosure is not limited thereto, for example, each of a plurality of pixels PX disposed in each of the plurality of display devices 100-1, 100-2, 100-3 . . . 100-M and 100-N may include a plurality of sub-pixels SP1, SP2, SP3 and SP4. Each of the plurality of sub-pixels SP1, SP2, SP3 and SP4 may include a first light-emitting element, a second light-emitting element, a third light-emitting element or a fourth light-emitting element that emits red (R), green (G), blue (B) or white (W) light, respectively. The light-emitting element according to an embodiment of the present disclosure may be embodied as a micro-LED. The micro-LED may refer to an LED made of an inorganic material and may have a size of 100 μm or smaller or may be a light-emitting element free of a growth substrate for growing the LED.

In one example, when the tiling display apparatus 100 is implemented by connecting the plurality of display devices 100-1, 100-2, 100-3 . . . 100-M and 100-N with each other, a spacing between the pixel PX located at the outermost position of one display device and the pixel PX located at the outermost position of another display device adjacent thereto may be the same as a spacing between adjacent pixels PXs located in each display device. For example, the spacing between the pixel PX located at the outermost position of one display device and the pixel PX located at the outermost position of another display device adjacent thereto is a distance between the center of the two pixels PXs, and the spacing between adjacent pixels PXs located in each display device is a distance between the center of the adjacent pixels PXs. Accordingly, the bezel arca may be disposed in a minimum space or a zero bezel area in which the bezel area is substantially absent may be implemented. When a space occupied by the bezel area is reduced or minimized, a display arca increases, such that the user recognizes that images appear continuously without discontinuity, and thus the user's screen immersion may increase.

In this case, the quality of the displayed image may be improved by implementing a side surface structure of the display device so that a seam area as a boundary area between adjacent display devices is not recognized by the user. For example, referring to FIG. 2. One display device among the plurality of display devices 100-1, 100-2, 100-3 . . . 100-M and 100-N may have a configuration in which a first substrate 110 and a second substrate 113 are bonded to each other. The first substrate 110 may include a display area AA and a non-display area NAA disposed in the vicinity of the display area AA or surrounding the display area AA. The second substrate 113 serves to support components disposed at a lower layer of the display device, and for example, a printed circuit board or the like may be disposed on the second substrate 113. In this regard, the first substrate 110 may be referred to as an upper substrate. The second substrate 113 may be referred to as a lower substrate.

The display area AA on the first substrate 110 is an area where the image is displayed. In the display arca AA, a plurality of signal lines (e.g., data lines, gate lines, power supply lines, clock lines etc.) that transmit various signals to the plurality of sub-pixels disposed in each of the plurality of pixels PX are disposed. The non-display area NAA is an area where images are not displayed. A link line and a pad electrode for transmitting a signal to the plurality of pixels PX of the display arca AA may be disposed in the non-display area NAA.

A plurality of side wiring 210 may be disposed at least one outer side surface of each of the first substrate 110 and the second substrate 113 so as to electrically connect the first substrate 110 and the second substrate 113 to each other. Adjacent side wirings 210a and 210b may be spaced apart from each other by a predetermined distance d in one direction.

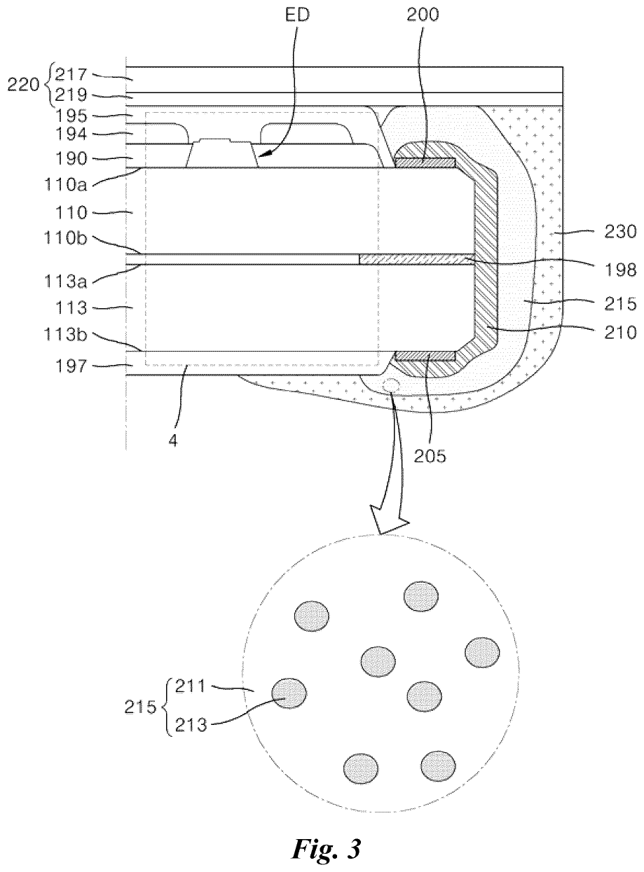

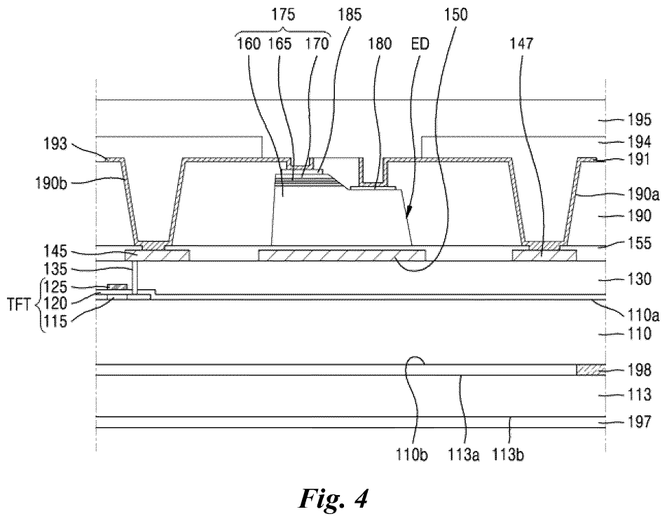

FIG. 3 is a cross-sectional taken along the line 3-3 in FIG. 1. FIG. 4 is an enlarged view of reference 4 in FIG. 3. In this regard, in the drawing, only a light-emitting element ED located at the outermost position of the display device is shown for convenience of illustration, but the present disclosure is not limited thereto.

Referring to FIG. 3 and FIG. 4, the substrates include the first substrate 110 and the second substrate 113. The first substrate 110 and the second substrate 113 are bonded to each other via an adhesive 198. The adhesive 198 is illustrated as being disposed only on the outermost position of each of the first substrate 110 and the second substrate 113. However, the present disclosure is not limited thereto. In one example, the adhesive 198 may be disposed over an entire area of a rear surface of the first substrate 110 and a front surface of the second substrate 113. Alternatively, the adhesive 198 may also be disposed over at least a portion of the area of a rear surface of the first substrate 110 and a front surface of the second substrate 113.

Each of the first substrate 110 and the second substrate 113 may include a transparent material including glass or plastic. However, the present disclosure is not limited thereto. For example, each of the first substrate 110 and the second substrate 113 may be made of a flexible transparent material. For example, each of the first substrate 110 and the second substrate 113 may include a flexible polymer film. The flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC) film, polyvinyl alcohol(PVA) film, and polystyrene(PS), and the present disclosure is not limited thereto. Further, the first substrate 110 and the second substrate 113 may be made of the same material as each other, or may be made of different materials.

On the first substrate 110, a light-emitting element ED, a thin-film transistor TFT for driving the light-emitting element ED and various lines are disposed. A first planarization layer 190 is disposed on the first substrate 110. The first planarization layer 190 may cover a side surface of the light-emitting element ED. A bank 194 having a bank hole defined therein may be disposed on the first planarization layer 190. A sealing layer 195 may be disposed on the bank 194. The sealing layer 195 may be formed to cover outer surfaces of the bank 194 and the first planarization layer 190.

A first pad electrode 200 is disposed on the outermost position of the first substrate 110. A driver and a second pad electrode 205 may be disposed on a rear surface of the second substrate 113 bonded to the first substrate 110. The driver may include a timing controller for driving the light-emitting element ED disposed on the first substrate 110, and a gate driver and a data driver for applying a gate signal and a data signal to a gate line and a data line, respectively. The second pad electrode 205 is disposed at the outermost position of the second substrate 113. Each of the first pad electrode 200 and the second pad electrode 205 may include a conductive material or metal. The rear surface of the second substrate 113 may be covered with a second planarization layer 197.

The first pad electrode 200 disposed at the outermost position of the first substrate 110 and the second pad electrode 205 disposed at the outermost position of the second substrate 113 may overlap with the plurality of side wiring 210 and may be electrically connected to each other via the plurality of side wiring 210. Each of the plurality of side wiring 210 may have a shape surrounding each of the first pad electrode 200, the outer side surface of the first substrate 110, the side outer surface of the second substrate 113, and the second pad electrode 205. As shown in FIG. 2, the side wiring 210 may be arranged so as to be spaced apart from each other by a predetermined distance d in one direction while being disposed on the outer side surface of the display device. For example, the overlapping of the first pad electrode 200 and the second pad electrode 205 with the side wiring 210 ensures a secure electrical connection between the two electrodes. This connection is established via the side wiring 210, which acts as a conductive bridge, enabling the flow of electrical signals between the electrodes. Moreover, the side wiring 210 encircles the first pad electrode 200, the outer side surface of the first substrate 110, the side outer surface of the second substrate 113, and the second pad electrode 205. This arrangement contributes to the overall stability and integrity of the electrical connections throughout the display device. In addition, as depicted in FIG. 2, the side wiring 210 is strategically spaced apart from each other, maintaining a predetermined distance d in one direction. This configuration prevents any potential short-circuits or interference caused by the proximity of the side wiring 210, thereby enhancing the reliability and performance of the display device.

The side wiring 210 transmits a signal transmitted from the driver disposed on the rear surface of the second substrate 113 to the first substrate 110 so that the light-emitting element ED disposed on the first substrate 110 may emit light. The lower the contact resistance, the faster the signal transmitted from the second substrate 113 may be transmitted to the light-emitting element ED on the first substrate 110. Accordingly, in one embodiment, the side wiring 210 preferably has a low contact resistance at a portion thereof in contact with each of the first pad electrode 200 and the second pad electrode 205. To this end, the side wiring 210 may include a conductive material or a metal material. In one example, the side wiring 210 may include silver (Ag) or copper (Cu), but the present disclosure is not limited thereto. Herein, the side wiring 210 serves as a critical link between the driver on the second substrate 113 and the light-emitting element ED on the first substrate 110. By ensuring a low contact resistance at the points where the side wiring 210 contacts the first pad electrode 200 and the second pad electrode 205, the speed of signal transmission from the driver to the light-emitting element ED is optimized, resulting in efficient and effective light emission.

A wiring protection member 215 may be disposed on the plurality of side wiring 210. The wiring protection member 215 may be disposed to surround an exposed outer side surface of each of the plurality of side wiring 210. The wiring protection member 215 may cover a portion of the sealing layer 195 located on the outermost position of the first substrate 110 and cover a portion of a side surface of the second planarization layer 197 located on the outermost position of the second substrate 113.

The wiring protection member 215 may include a protection layer 211 and conductive particles 213 dispersed in the protection layer 211. The wiring protection member 215 serves to prevent abnormal phenomena such as migration of a conductive material or a metal material constituting the side wiring 210. The migration phenomenon may be understood as a phenomenon in which a metal component constituting the plurality of side wiring 210 is ionized and diffused to the surroundings. When the migration phenomenon occurs, the metal component constituting the side wiring 210 diffuses to the surroundings such that a short circuit may occur between adjacent side wiring 210.

Accordingly, the wiring protection member 215 according to an embodiment of the present disclosure includes the protection layer 211 and the conductive particles 213 dispersed therein. Thus, the wiring protection member 215 may be disposed between adjacent ones of the plurality of side wirings 210 so as to prevent the metal component from diffusing to the surroundings.

That is to say, the wiring protection member 215 acts as a barrier that safeguards the side wiring 210 from unwanted phenomena, such as the migration of metal components. By encapsulating the exposed outer side surfaces of the side wiring 210, the wiring protection member 215 not only protects the side wiring but also covers portions of the sealing layer 195 and the second planarization layer 197, contributing to the overall stability of the display device.

The presence of conductive particles 213 within the protection layer 211 enhances the wiring protection member's ability to prevent migration of metal components from the side wiring 210. This design ensures that the metal components remain localized within the side wiring, reducing the risk of short circuits between adjacent side wiring 210 and maintaining the integrity and reliability of the display device.

The conductive particles 213 dispersed in the protection layer 211 may include indium (In) particles. The indium (In) particles may have a size (e.g., a diameter) of 1 μm-5 μm, preferably the indium (In) particle may have a size of 2 μm. The conductive particles 213 may have a content that does not exceed 80 wt % of a total weight of the protection layer 211. When the content of the conductive particles 213 exceeds 80 wt %, a resistance value of the wiring protection member 215 is lower than 10602/0, and thus a short circuit may occur. For example, the conductive particles 213 are preferably contained in a content range of 10 wt % to 70 wt %. As the resistance value of the wiring protection member 215 is maintained to have a value higher than 10⁶ Ω/□, the wiring protection member 215 may be prevented from having electrical conductivity. The conductive particles 213 dispersed in the protection layer 211 is not limited thereto, for example. As long as the design requirement in which resistance value of the wiring protection member 215 is maintained to have a value higher than 10⁶ Ω/□ and the conductive particle 213 is contained in a content range of 10 wt % to 70 wt % is satisfied, the conductive particles 213 may be other metal particles.

The protection layer 211 may further contain a light blocking material, a binder resin, a curing agent, and a solvent. When the plurality of side wiring 210 are made of a metal material, there is a problem in that external light is reflected from the side wiring 210 or light emitted from the light-emitting element ED is reflected from the side wiring 210, and the reflected light is recognized by the user. Therefore, the protection layer 211 may contain a light blocking material capable of blocking light, including, for example, a material capable of blocking light such as black ink or carbon black, but the present disclosure is not limited thereto. In present disclosure, incorporating a light blocking material, such as black ink or carbon black, into the protection layer 211 effectively blocks and absorbs the undesired light reflections. This enhancement minimizes the visual impact of reflections on the user and improves the overall display quality.

A side sealing member 230 may be disposed on the wiring protection member 215. The side sealing member 230 may be formed to cover the wiring protection member 215. The side sealing member 230 may extend to cover a portion of the second planarization layer 197 located on the second substrate 113 while covering a portion of the wiring protection member 215 located on the second substrate 113.

A cover member 220 may be disposed on the side sealing member 230, the wiring protection member 215, and the sealing layer 195. The cover member 220 may include glass or plastic. However, the present disclosure is not limited thereto. The cover member 220 may include a functional optical film such as an anti-scattering film. For example, the cover member 220 may include a base film 217 and an optical clear adhesive (OCA) 219 attached to one surface of the base film 217.

The cover member 220 may be bonded to the side scaling member 230, the wiring protection member 215, and the sealing layer 195 via the OCA 219. The outermost side surface of the side sealing member 230 may be aligned with the outermost side surface of the cover member 220 in the same plane.

In one example, the first substrate 110 may have a light-emitting element ED, a thin-film transistor TFT for driving the light-emitting element ED, and various lines disposed thereon. Hereinafter, a portion of an area where the light-emitting element ED of FIG. 3 is disposed will be described with reference to FIG. 4 as an enlarged view thereof. Referring to FIG. 4, the thin-film transistor TFT driving the light-emitting element ED is disposed on the first surface 110a of the first substrate 110. The first surface 113a of the second substrate 113 may face the second surface 110b opposite to the first surface 110a of the first substrate 110. The driver and the second pad electrode 205 may be disposed on the second substrate 113. The second planarization layer 197 may be disposed on the second surface 113b of the second substrate 113. The first substrate 110 or the second substrate 113 may include a transparent material including glass or plastic.

The thin-film transistor TFT includes a semiconductor layer 115 formed on the first surface 110a of the first substrate 110, a gate electrode 125 positioned on the semiconductor layer 115, and a gate insulating layer 120 positioned between the semiconductor layer 115 and the gate electrode 125.

The semiconductor layer 115 may include a polycrystalline semiconductor material, an amorphous semiconductor material and an oxide semiconductor material.

The polycrystalline semiconductor material has a fast movement speed of carriers such as electrons and holes and thus has high mobility, and has low energy power consumption and superior reliability. The polycrystalline semiconductor may be made of polysilicon, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The semiconductor layer 115 may include an active area overlapping the gate electrode 125 to constitute a channel, and a source area and a drain area respectively located on both opposing sides of the active area interposed therebetween. An interlayer insulating film 130 is disposed on the gate electrode 125. The interlayer insulating film 130 may receive therein source/drain electrodes 135 extending through the gate insulating layer 120 so as to be respectively electrically connected to the source/drain areas of the semiconductor layer 115.

A connection electrode 145, a wiring line 147, and a reflective layer 150 may be disposed on the interlayer insulating film 130. The connection electrode 145, the wiring line 147, and the reflective layer 150 may be disposed in the same plane or coplanar with each other. In one example, the wiring line 147 may include a common voltage line. A protection layer 155 covering the connection electrode 145, the wiring line 147, and the reflective layer 150 is disposed on the interlayer insulating film 130. The protection layer 155 may not cover a portion of an upper surface of each of the connection electrode 145 and the wiring line 147 so as to be exposed.

The light-emitting element ED may be disposed on the protection layer 155 at a position corresponding to a position where the reflective layer 150 is disposed. The light-emitting element ED according to an embodiment of the present disclosure may be embodied as a micro-LED. The micro-LED may be an LED made of an inorganic material and may be a light-emitting element of a size of 100 μm or smaller or free of a growth substrate for growing the LED. Further, in an embodiment of the present disclosure, a horizontal micro-LED is described by way of example. However, the present disclosure is not limited thereto. For example, the light-emitting element may be embodied as a vertical micro-LED, a flip chip micro-LED, or a nanorod micro-LED.

The light-emitting element ED may include a nitride semiconductor structure 175, a first electrode 180 and a second electrode 185. The nitride semiconductor structure 175 may include a first semiconductor layer 160, an active layer 165 disposed on one side of a top surface of the first semiconductor layer 160, and a second semiconductor layer 170 disposed on the active layer 165. The first electrode 180 is disposed on the other side of the top surface of the first semiconductor layer 160 where the active layer 165 is not located. The second electrode 185 is disposed on the second semiconductor layer 170.

The first semiconductor layer 160 is a layer for supplying electrons to the active layer 165, and may include a nitride semiconductor containing the first conductivity type impurities. For example, the first conductivity-type impurity may include an N-type impurity. The active layer 165 disposed on one side of the top surface of the first semiconductor layer 160 may have a multi-quantum well (MQW) structure. The second semiconductor layer 170 is a layer for injecting holes into the active layer 165. The second semiconductor layer 170 may include a nitride semiconductor containing the second conductivity type impurity. For example, the second conductivity type impurity may include a P-type impurity. Herein, the multi-quantum well (MQW) structure in the active layer 165 may enhance the efficiency of carrier confinement and recombination, leading to higher performance in the overall device.

The reflective layer 150 serves to reflect light beams directed toward the rear surface 110b of the first substrate 110 among light beams emitted from the light-emitting element ED toward the light-emitting area 110a, that is, toward the front surface 110a of the first substrate 110.

The light-emitting element ED may be covered by the first planarization layer 190. The first planarization layer 190 may have a thickness sufficient to planarize an upper surface having a step caused by underlying circuit elements. A first contact-hole 190a and a second contact-hole 190b may be formed in the first planarization layer 190 to expose portions of surfaces of the wiring line 147 and the connection electrode 145, respectively. Further, the first planarization layer 190 may not cover a portion of an upper surface of each of the first electrode 180 and the second electrode 185 of the light-emitting element ED so as to be exposed.

A first line electrode 191 and a second line electrode 193 may be disposed on exposed surfaces of the first contact-hole 190a and the second contact-hole 190b, respectively, so as to be electrically connected to the wiring line 147 and the drain electrode of the semiconductor layer 115 of the thin-film transistor TFT, respectively. Further, the first line electrode 191 may be electrically connected to the first electrode 180. The second line electrode 193 may be electrically connected to the second electrode 185. The first line electrode 191 and the second line electrode 193 may be made of the same material. In one example, the first line electrode 191 or the second line electrode 193 may include a transparent metal oxide such as indium-tin-oxide (ITO) or indium-zinc-oxide (IZO). However, the present disclosure is not limited thereto. The first line electrode 191 and the second line electrode 193 may also be made of the different materials.

The bank 194 having a bank hole defined therein is disposed on the first planarization layer 190. The bank 194 is a boundary area defining the light-emitting area and plays a role in defining each sub-pixel. In one example, the first contact-hole 190a and the second contact-hole 190b on which the first line electrode 191 and the second line electrode 193 have been respectively formed may be filled with a material constituting the bank 194. Although not shown in the drawing, a black matrix may be disposed on the bank 194 to reduce light leakage and improve the contrast ratio of the display by absorbing ambient light, which results in enhanced image quality and visibility in various lighting conditions. The sealing layer 195 may be disposed on the first substrate 110 including the bank 194 so as to provide additional protection for the underlying components and helps maintain the structural integrity of the device.

In the display device according to an embodiment of the present disclosure, the wiring protection member 215 protecting the side wiring 210 includes the protection layer 211 and the conductive particles 213 dispersed in the protection layer 211. The wiring protection member 215 suppresses a migration phenomenon in which a metal component constituting the side wiring 210 is ionized and diffuses to the surroundings, thereby preventing a short-circuit defect between adjacent side wirings 210 from occurring. This may improve the product reliability of the display device and may prevent the degradation of product life due to the migration phenomenon. Further, suppressing the migration phenomenon may prevent increase in power consumption due to the short circuit between side wirings 210, thereby implementing a low-power product.

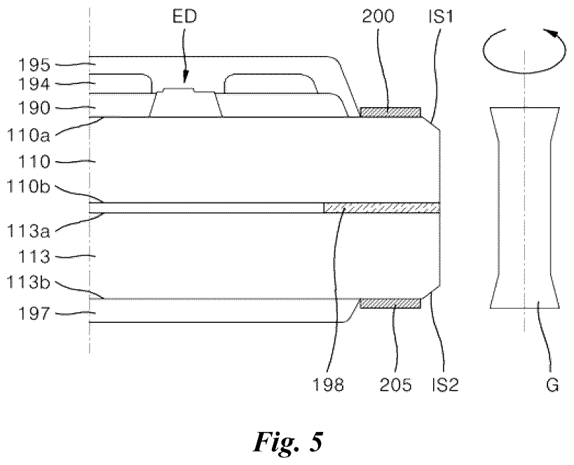

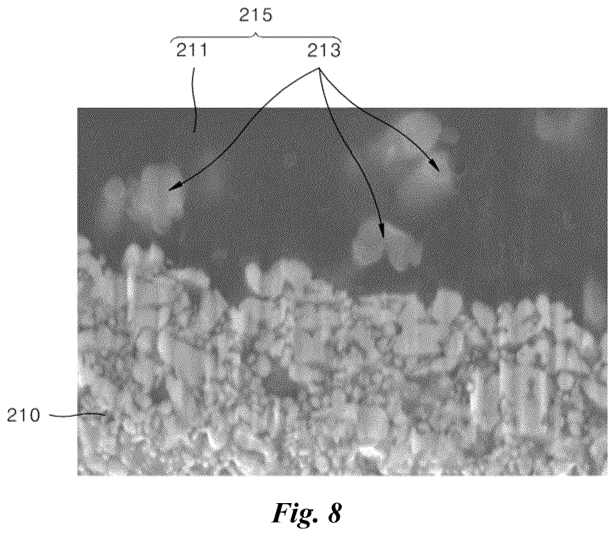

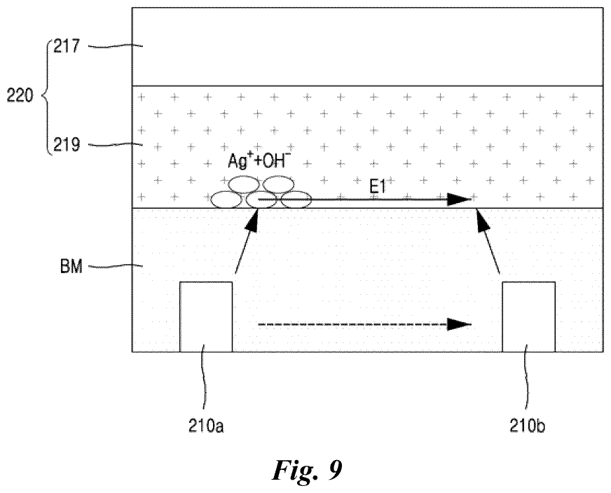

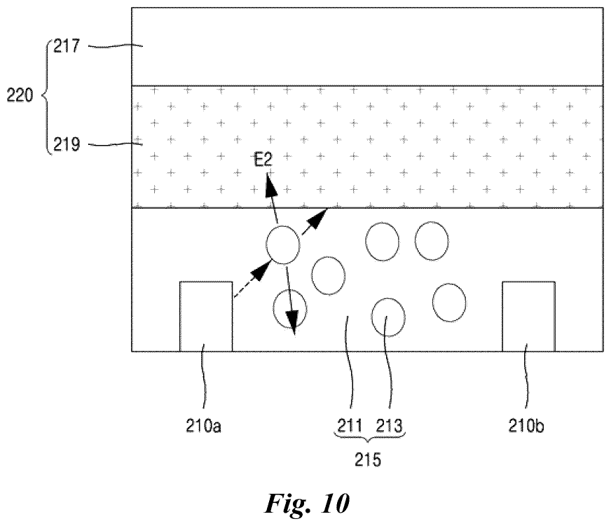

FIG. 5 to FIG. 11 are diagrams shown to illustrate a manufacturing method of a display device according to an embodiment of the present disclosure. FIG. 8 is an enlarged SEM picture of the side wiring and the wiring protection member. FIG. 9 and FIG. 10 are diagrams shown to illustrate the migration phenomenon.

Referring to FIG. 5, the substrates 110 and 113 are prepared, wherein the light-emitting element ED is disposed on the substrate 110. Then, inclined surfaces IS1 and IS2 are formed at the outermost portions of the substrates 110 and 113, respectively. The inclined surfaces IS1 and IS2 respectively disposed at the outermost portions of the substrates 110 and 113 may be formed using a grind wheel device G.

The substrates 110 and 113 include the first substrate 110 and the second substrate 113. The first substrate 110 and the second substrate 113 are bonded to each other via the adhesive 198. The first substrate 110 may include the first surface 110a on which the light-emitting element ED is disposed, the second surface 110b opposite the first surface 110a, and a first side surface disposed between the first surface 110a and the second surface 110b. The first surface 113a of the second substrate 113 may be bonded to the second surface 110b opposite to the first surface 110a of the first substrate 110. The second substrate 113 may include the first surface 113a bonded to the first substrate 110, the second surface 113b opposite to the first surface 113a, and a second side surface disposed between the first surface 113a and the second surface 113b.

The light-emitting element ED in FIG. 5 may be embodied as the micro-LED in an embodiment of the present disclosure. However, the present disclosure is not limited thereto. When the light-emitting element ED is embodied as the micro-LED, the micro-LED in FIG. 5 has the same configuration as that of the micro-LED as described in FIG. 4, a detailed description thereof will be omitted or will be briefly provided.

The inclined surfaces IS1 and IS2 respectively disposed at the outermost portions of the substrates 110 and 113 may include the first inclined surface IS1 disposed above the first side surface of the first substrate 110 and the second inclined surface IS2 disposed under the second side surface of the second substrate 110. The inclined surfaces IS1 and IS2 may prevent edges of the substrates from colliding with each other and being damaged when the plurality of display devices 100-1, 100-2, 100-3 . . . 100-M, 100-N(see FIG. 1) are arranged and assembled with each other. The grind wheel device G may cut corners from the surfaces of the outermost portions of the substrates 110 and 113 to form the inclined surfaces IS1 and IS2.

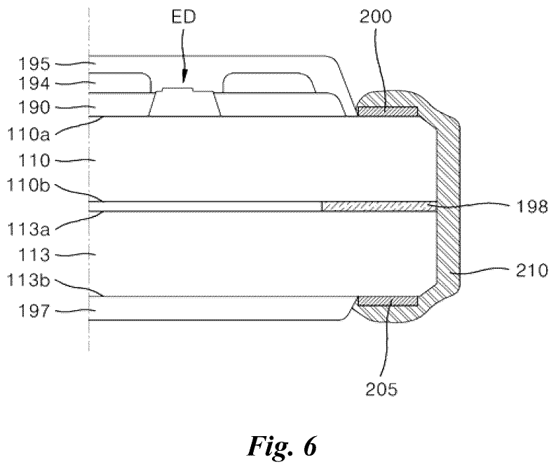

Referring to FIG. 6, the side wiring 210 is formed on the side surfaces of the first substrate 110 and the second substrate 113. The side wiring 210 may electrically connect the first pad electrode 200 disposed at the outermost position of the first substrate 110 and the second pad electrode 205 disposed at the outermost position of the second substrate 113 to each other. The side wiring 210 may include a conductive material or a metal material. In one example, the side wiring 210 may include silver (Ag), but the present disclosure is not limited thereto. The side wiring 210 may be formed by applying a conductive material or a metal material in a form of a paste to the side surfaces of the first substrate 110 and the second substrate 113 and performing a drying and curing process thereon.

The side wiring 210 transmits a signal transmitted from the driver disposed on the rear surface of the second substrate 113 to the light-emitting element ED disposed on the first substrate 110 so as to emit light. The plurality of side wiring 210 may be disposed on at least one outer side surface of each of the first substrate 110 and the second substrate 113. Adjacent side wiring 210 may be spaced apart from each other.

Each of the side wiring 210 may cover the first pad electrode 200 disposed on the first surface 110a of the first substrate 110 and may extend along and on the side surface of the first substrate 110 and the side surface of the second substrate 113 and may cover the second pad electrode 205 disposed on the surface 113b of the second substrate 113.

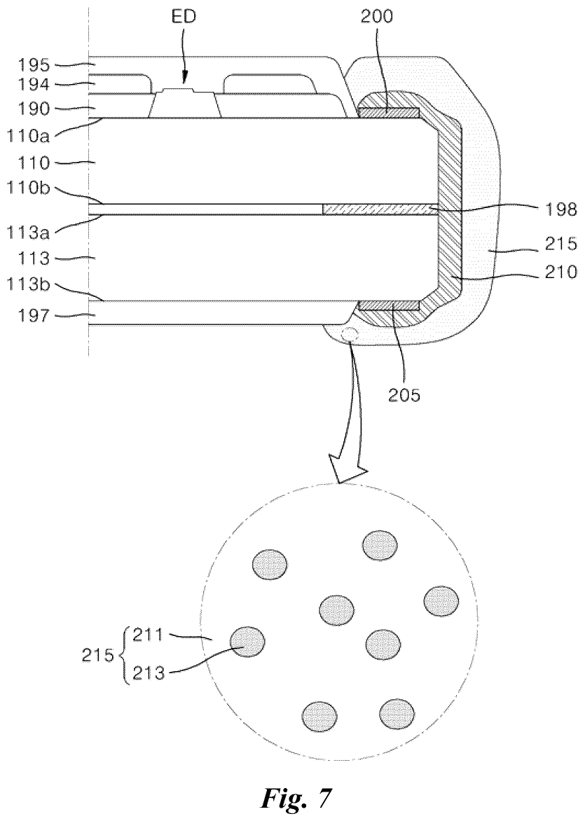

Referring to FIG. 7 and FIG. 8, the wiring protection member 215 is formed on the plurality of side wiring 210. The wiring protection member 215 serves to prevent abnormal phenomenon such as migration of the conductive material or the metal material constituting the side wiring 210. Further, the wiring protection member 215 prevents the side wiring 210 from being damaged by the external environment.

The wiring protection member 215 may include the protection layer 211 and the conductive particles 213 dispersed in the protection layer 211. The protection layer 211 may further include a light blocking material, a binder resin, a curing agent and a solvent. The light blocking material prevents external light or light emitted from the light-emitting element ED from being recognized by a user, and may include black ink or carbon black. The binder resin may improve adhesion, and the solvent may facilitate application of the wiring protection member 215.

In one example, the wiring protection member 215 may be formed using a pad-printing scheme. The pad-printing scheme may be understood as a scheme in which the protection layer 211 is applied on a printing pad made of silicon and then the printing pad is brought into contact with each of the side surfaces of the first substrate 110 and the second substrate 113 such that the protection layer 211 is formed thereon.

The conductive particles 213 dispersed in the protection layer 211 may include indium (In) particles. The indium (In) particles may have a size (e.g., a diameter) of 1 μm-5 μm, preferably the indium (In) particle may have a size of 2 μm. The conductive particles 213 may have a content such that a weight thereof does not exceed 80% of a total weight of the protection layer 211. When the weight of the conductive particles 213 exceeds 80% of the total weight of the protection layer 211, the resistance value of the wiring protection member 215 is lower than 10602/u and becomes conductive, which may cause a short circuit defect.

Hereinafter, a description will be made with reference to [Table 1].

| In content (wt %) | 10 | 30 | 50 | 70 | 80 | 90 |
|---|---|---|---|---|---|---|
| Surface | 1*10¹² or | (7 to 9)*10¹¹ | (1 to 3)*10¹¹ | (2 to 6)*10⁸ | (1 to 2)*10⁶ | (3 to 5)*10³ |
| resistance | higher | | | | | |
| Whether | No | No | No | No | Yes | Yes |
| short circuit | | | | | | |
| occurs | | | | | | |

In [Table 1], the surface resistance is expressed in Ω/□ unit.

Referring to [Table 1], it may be identified that no short circuit occurs when the indium (In) particles as the conductive particles 213 dispersed in the protection layer 211 are contained in a content range of 10 wt % to 70 wt %. In contrast, it may be identified that a short circuit occurs when the indium (In) particles are contained at a content of 80 wt %. Accordingly, in one embodiment, the conductive particles 213 are preferably contained in the protection layer 211 in a content range of 10 wt % to 70 wt %. As the wiring protection member 215 according to an embodiment of the present disclosure is maintained at a resistance value higher than 10⁶ Ω/□, this can prevent the wiring protection member 215 from having electrical conductivity. Meanwhile, the conductive particles 213 dispersed in the protection layer 211 is not limited thereto, for example, the conductive particles 213 dispersed in the protection layer 211 may include tin (Sn) particles.

In one example, a reliability test of the display device is conducted in a high temperature and high humidity environment. For example, the test may be conducted in an environment with a temperature of 85° C. and humidity of 85%. In this case, the wiring protection member is made of a single material of black ink and the reliability test of a display panel is conducted in a high temperature and high humidity environment. Thus, it is identified that silver (Ag) ions are precipitated when the evaluation time of 44 hours has elapsed. In contrast, it is identified that when the wiring protection member including the protective layer having the conductive particles dispersed therein according to an embodiment of the present disclosure, silver (Ag) ions are not precipitated even after 164 hours of evaluation time has elapsed. In other words, the reliability of the product may be secured.

This will be described with reference to FIG. 9 and FIG. 10. when performing the reliability test on the display device in a high temperature and high humidity environment, a migration phenomenon may occur in the side wiring 210 made of a metal material including silver (Ag). The migration phenomenon may refer to a phenomenon in which silver (Ag) as the metal component constituting the side wiring 210 is ionized to silver ion (Ag⁺) and diffused to the surroundings.

The ionized silver (Ag⁺) may be moved by the electric field E-field. When the ionized silver (Ag⁺) is coupled to hydroxide ion (OH⁻), silver (Ag) may be precipitated. In this regard, the stronger the electric field, the faster the precipitation of silver (Ag).

Accordingly, the wiring protection member including the black ink is disposed between adjacent side wirings to prevent the migration phenomenon, however, the migration phenomenon still occurs. Referring to FIG. 9, the black ink BM constituting the wiring protection member is disposed between adjacent side wirings 210a and 210b. The cover member 220 is disposed on the black ink BM. The cover member includes the base film 217 and the optical clear adhesive (OCA) 219 attached to a bottom surface of the base film 217. In this regard, when a voltage is applied onto the side wirings 210a and 210b, the ionized silver (Ag⁺) passes through the black ink BM without a change in the strength of the electric field E1, and then the ionized silver (Ag⁺) is coupled to hydroxide ion (OH⁻) by moisture (H₂O) inside the optical clear adhesive (OCA) 219 and thus the silver (Ag) is precipitated. Then, as indicated by an arrow, the silver (Ag) may migrate from one side wiring 210a to another side wiring 210b adjacent thereto along the direction of the electric field E1, such that the short circuit occurs between the side wirings 210a and 201b, which causes the display device to not operate.

However, referring to FIG. 10 according to an embodiment of the present disclosure, the wiring protection member 215 including the protection layer 211 and the conductive particles 213 dispersed therein is disposed between adjacent side wirings 210a and 210b. The cover member 220 is disposed on the wiring protection member 215. The cover member includes the base film 217 and the optical clear adhesive (OCA) 219 attached to a bottom surface of the base film 217.

The conductive particles 213 dispersed within the protection layer 211 can diversify the directionality of the electric field E2 generated in a direction perpendicular to a conductor surface into various directions, as indicated by the arrows in FIG. 10. This may weaken the strength of the electric field E2 directed toward the optical clear adhesive 219 containing the moisture (H₂O). Accordingly, the combination of the ionized silver (Ag⁺) with hydroxide ion (OH) may be delayed such that the migration occurrence time may be delayed. As a result, when the wiring protection member includes the protective layer including the conductive particles dispersed therein according to an embodiment of the present disclosure, the silver (Ag) is not precipitated even after 164 hours of evaluation time. This may prevent the occurrence of defects in which the display device fails to operate due to the migration phenomenon.

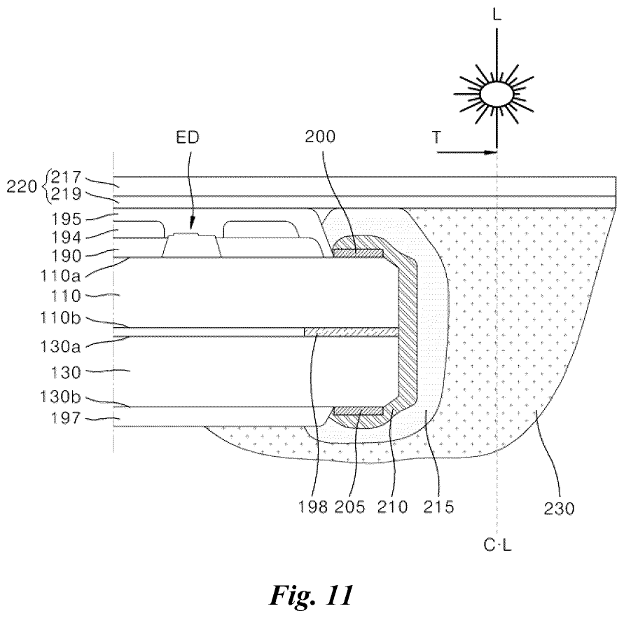

Referring to FIG. 11, the cover member 220 may be disposed on the sealing layer 195 and the wiring protection member 215. The cover member 220 may protect the light-emitting element ED from external impact. The cover member 220 may include glass or plastic. However, the present disclosure is not limited thereto. For example, the cover member 220 may further include a functional optical film such as an anti-scattering film. The cover member 220 may include the base film 217 and the optical clear adhesive (OCA) 219 attached to a bottom surface of the base film 217.

The base film 217 of the cover member 220 may be disposed on the sealing layer 195 and the wiring protection member 215 while the optical clear adhesive (OCA) 219 is disposed therebetween.

Subsequently, the side sealing member 230 is formed on the side surfaces of the first substrate 110 and the second substrate 113. The side sealing member 230 serves to protect the driver disposed on the side wiring 210 and the second substrate 113. The side sealing member 230 may be formed to have a thickness sufficient to cover both the side surfaces of the first substrate 110 and the second substrate 113. The side sealing member 230 may be formed by extend so as to cover a portion of the surface of the second planarization layer 197 disposed on the second substrate 113 in order to protect the driver disposed on the second substrate 113.

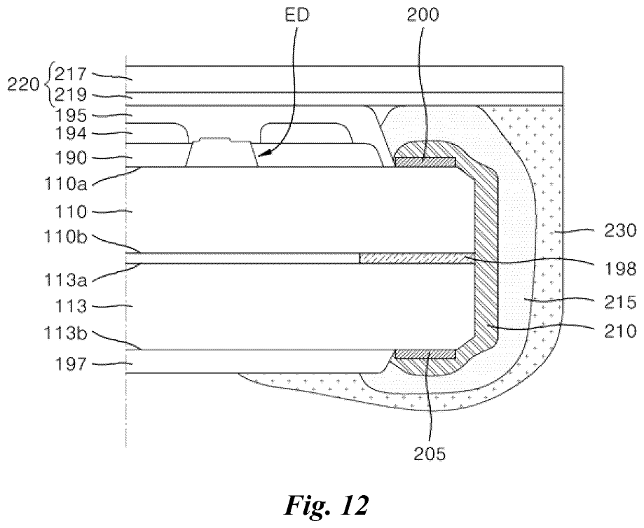

Referring to FIG. 11 and FIG. 12, a laser cutting process of cutting the side scaling member 230 along a cutting line C.L shown in FIG. 11 using a laser device L is performed. Thus, the outer side surface of the cut side sealing member 230 may be aligned with the outermost side surface of the cover member 220 in the same plane.

The laser cutting process cuts a portion of a width of each of the cover member 220 and the side sealing member 230 to implement that the bezel area T is disposed in a minimum space or to implement a zero bezel area where the bezel area T is absent. The cutting process using the laser device L may be performed by repeatedly irradiating a laser beam onto the side sealing member 230. According to one embodiment, during the laser cutting process, the laser beam may be irradiated to the cutting line C.L as a target point in a repeated manner.

According to the embodiments of the present disclosure, the wiring protection member that protects the side wiring used to electrically connect the upper substrate and the lower substrate to each other in the display device includes the protective layer and the conductive particles dispersed in the protective layer. Thus, the conductive particles contained in the wiring protection member may diversify the direction of the electric field, thereby preventing increase in the electric field intensity that may accelerate the time of the migration of metal ions, thereby suppressing a migration phenomenon in which metal ions of one side wiring move to another side wiring adjacent thereto.

Accordingly, there is an effect of delaying the occurrence time of the migration phenomenon in which the metal ions of the side wiring move to the adjacent side wirings. This may suppress occurrence of a short-circuit defect between adjacent side wirings due to the migration phenomenon.

Further, delaying the migration occurrence time may result in preventing a defect in which an image is not displayed on a display area of the display device, such that product reliability may be improved.

Further, delaying the time at which the migration phenomenon occurs may result in improving the lifespan of the product and suppressing the increase in the power consumption to implement a low-power product.

Further, controlling a width of the side sealing member via the laser cutting may allow the bezel area to be disposed in a minimum space or to implement a zero bezel area in which a bezel area is substantially absent.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents. U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate including light-emitting elements disposed over one surface thereof;
a second substrate bonded to an opposite surface to the one surface of the first substrate;
a plurality of side wirings electrically connecting the first substrate and the second substrate to each other; and
a wiring protection member covering plurality of side wirings,
wherein the wiring protection member includes a protective layer and a plurality of conductive particles dispersed in the protective layer.

2. The display device of claim 1, further comprising a side sealing member covering an exposed surface of the wiring protection member.

3. The display device of claim 1, wherein the plurality of side wirings is disposed on at least one outer side surface of each of the first substrate and the second substrate, and are arranged so as to be spaced apart from each other in one direction.

4. The display device of claim 1, wherein a first pad electrode is disposed over an outermost position of the first substrate,
wherein a second pad electrode is disposed over an outermost position of the second substrate, and
wherein each side wiring of the plurality of side wirings contacts and overlaps the first pad electrode and the second pad electrode.

5. The display device of claim 2, wherein the display device further comprises a cover member disposed on the side sealing member and the first substrate, and
wherein an outermost side surface of the side sealing member is aligned with an outermost side surface of the cover member in a same plane.

6. The display device of claim 1, wherein the conductive particles dispersed in the protection layer include metal particles.

7. The display device of claim 6, wherein the metal particles include indium (In) particles.

8. The display device of claim 7, wherein a weight of the indium (In) particles are less than 80% of a total weight of the protective layer.

9. The display device of claim 7, wherein a weight of the indium (In) particles is in a range of 10% to 70% of a total weight of the protective layer.

10. The display device of claim 1, wherein the wiring protection member including the protective layer and the plurality of conductive particles dispersed in the protective layer has a surface resistance value higher than 106 Ω/□.

11. The display device of claim 1, wherein the protective layer further includes at least one of a light-blocking material, a binder resin, a curing agent, and a solvent.

12. The display device of claim 11, wherein the light-blocking material includes black ink or carbon black.

13. The display device of claim 2, wherein the wiring protection member including the protective layer and the plurality of conductive particles dispersed in the protective layer, in operation, prevents migration of metal ions between adjacent side wirings.

14. A tiling display apparatus comprising a plurality of display devices arranged in a tiling manner,
wherein each of the plurality of display devices includes the display device including:
a first substrate having a plurality of light-emitting elements disposed over one surface thereof;
a second substrate bonded to an opposite surface to the one surface of the first substrate;
a plurality of side wirings electrically connecting the first substrate and the second substrate to each other,
a wiring protection member covering the side wiring; and
a side sealing member covering a side surface portion,
wherein the wiring protection member includes a protective layer and a plurality of conductive particles dispersed in the protective layer, and
wherein the plurality of display devices is arranged such that the side sealing members of adjacent ones of the plurality of display devices are adjacent to each other.
